(19) United States
(12) Patent Application Publication
(10) Pub. No.: US 2022/0376051 A1
(43) Pub. Date: Nov. 24, 2022

(54) SEMICONDUCTOR DEVICE

(71) Applicant: ROHM CO., LTD., Kyoto (JP)

(72) Inventor: Yasunobu HAYASHI, Kyoto (JP)

(73) Assignee: ROHM CO., LTD., Kyoto (JP)

(21) Appl. No.: 17/775,524

(22) PCT Filed: Nov. 30, 2020
(86) PCT No.: PCT/JP2020/044554

§ 371 Date: May 9, 2022

(30) Foreign Application Priority Data
Dec. 6, 2019 (JP) 2019-221394

(51) Int. Cl. H01L 29/10; H01L 21/74

(52) U.S. Cl. CPC H01L 29/1087; H01L 21/743

(57) ABSTRACT

A semiconductor device includes a semiconductor layer, a source region and a drain region that are formed in the semiconductor layer and at an interval in a first direction, a gate insulating film that is formed such as to cover a channel region between the source region and the drain region, and a gate electrode that is formed on the gate insulating film and opposes the channel region across the gate insulating film. The gate insulating film has a major portion on which the gate electrode is formed and extension portions projecting outward from each of both sides of the major portion in a second direction orthogonal to the first direction and leak current suppressing electrodes are formed on the extension portions.

### TECHNICAL FIELD

The present invention relates to a semiconductor device such as a MOS (metal oxide semiconductor) type transistor, etc.

### BACKGROUND ART

A p type MOS transistor has an n type well formed on an n type semiconductor substrate. A p type source region and a p type drain region are formed at an interval from each other in a surface layer portion of the n type well and a portion therebetween is arranged as a channel region. A gate electrode opposes the channel region across a gate insulating film.

### CITATION LIST

### Patent Literature

Patent Literature 1: Japanese Patent Application Publication No. 2013-115056

### SUMMARY OF INVENTION

### Technical Problem

With the p type MOS transistor, there is a problem that in a transistor-off state, a leak current flows from the p type source region to the p type drain region through a region of the n type well region that is peripheral to the gate electrode. Such a leak current becomes a cause of degradation with time.

In addition, a similar problem occurs in an n type MOS transistor. That is, with the n type MOS transistor, there is a problem that in a transistor-off state, a leak current flows from an n type drain region to an n type source region through a region of a p type well region that is peripheral to a gate electrode.

An object of the present invention is to provide a semiconductor device with which the leak current can be reduced.

### Solution to Problem

A preferred embodiment of the present invention provides a semiconductor device including a semiconductor layer, a source region and a drain region that are formed in the semiconductor layer and at an interval in a first direction, a gate insulating film that is formed such as to cover a channel region between the source region and the drain region, and a gate electrode that is formed on the gate insulating film and opposes the channel region across the gate insulating film and where the gate insulating film has a major portion on which the gate electrode is formed and an extension portion projecting outward from each of both sides of the major portion in a second direction orthogonal to the first direction and a leak current suppressing electrode is formed on the extension portion.

With this arrangement, it is made possible to reduce a leak current.

In the preferred embodiment of the present invention, a voltage equal to a voltage applied to the semiconductor layer is applied to the leak current suppressing electrode.

In the preferred embodiment of the present invention, a voltage equal to a voltage applied to the source region is applied to the leak current suppressing electrode and the semiconductor layer.

In the preferred embodiment of the present invention, a back gate region is formed in the semiconductor layer such as to surround the gate insulating film.

In the preferred embodiment of the present invention, an element isolation portion is formed in the semiconductor layer such as to surround the back gate region.

In the preferred embodiment of the present invention, the element isolation portion is an STI structure.

In the preferred embodiment of the present invention, at least a portion of the extension portion is formed in the same step as a step of forming the element isolation portion.

In the preferred embodiment of the present invention, the leak current suppressing electrode is electrically connected to the back gate region.

In the preferred embodiment of the present invention, the leak current suppressing electrode is formed in the same step as a step of forming the gate electrode.

A preferred embodiment of the present invention provides a method for manufacturing semiconductor device that is a method for manufacturing a semiconductor device having a source region and a drain region that are formed at an interval in a first direction, a gate insulating film that is formed such as to cover an interval between the regions, and a gate electrode that is formed on the gate insulating film, the gate insulating film having a major portion on which the gate electrode is formed and an extension portion projecting outward from each of both sides of the major portion in a second direction orthogonal to the first direction, and the method including a step of forming a first insulating layer that becomes a portion of the extension portion in a surface layer portion of a semiconductor substrate, a step of forming a first conductivity type well by selectively doping the semiconductor substrate with a first impurity of a first conductivity type, a step of selectively thermally oxidizing the semiconductor substrate to form the major portion and at the same time form a second insulating layer that becomes a portion of the extension portion to form the gate insulating film having the extension portion that is constituted of the first insulating layer and the second insulating layer and the major portion, a step of forming the gate electrode on the major portion and at the same time forming a leak current suppressing electrode on the extension portion, and a step of forming the source region and the drain region by selectively doping the first conductivity type well with an impurity of a second conductivity type.

With this manufacturing method, a semiconductor device by which the leak current can be reduced is obtained.

A preferred embodiment of the present invention provides a method for manufacturing semiconductor device that is a method for manufacturing a semiconductor device having a source region and a drain region that are formed at an interval in a first direction, a gate insulating film that is formed such as to cover an interval between the regions, and a gate electrode that is formed on the gate insulating film, the gate insulating film having a major portion on which the gate electrode is formed and an extension portion projecting outward from each of both sides of the major portion in a second direction orthogonal to the first direction, and the method including a step of forming a first conductivity type well by selectively doping the semiconductor substrate with a first impurity of a first conductivity type, a step of selectively thermally oxidizing the semiconductor substrate to form the gate insulating film, a step of forming the gate electrode on the major portion and at the same time forming a leak current suppressing electrode on the extension portion, and a step of forming the source region and the drain region by selectively doping the first conductivity type well with an impurity of a second conductivity type.

With this manufacturing method, a semiconductor device by which the leak current can be reduced is obtained.

In the preferred embodiment of the present invention, a step of forming a first conductivity type back gate region by selectively doping the first conductivity type well with a second impurity of the first conductivity type is further included.

In the preferred embodiment of the present invention, a step of electrically connecting the leak current suppressing electrode with the back gate region is further included.

The aforementioned as well as yet other objects, features, and effects of the present invention will be made clear by the following description of the preferred embodiments made with reference to the accompanying drawings.

### BRIEF DESCRIPTION OF DRAWINGS

FIG. 1 is an illustrative plan view for describing the arrangement of a semiconductor device according to a preferred embodiment of the present invention.

FIG. 2 is an illustrative sectional view taken along line II-II of FIG. 1.

FIG. 3 is an illustrative sectional view taken along line III-III of FIG. 1.

FIG. 4A is a sectional view of an example of a manufacturing process of the semiconductor device shown in FIG. 1 to FIG. 3 and is a sectional view corresponding to the section plane of FIG. 2.

FIG. 4B is a sectional view of a step subsequent to that of FIG. 4A.

FIG. 4C is a sectional view of a step subsequent to that of FIG. 4B.

FIG. 4D is a sectional view of a step subsequent to that of FIG. 4C.

FIG. 4E is a sectional view of a step subsequent to that of FIG. 4D.

FIG. 4F is a sectional view of a step subsequent to that of FIG. 4E.

FIG. 4G is a sectional view of a step subsequent to that of FIG. 4F.

FIG. 5A is a sectional view of the example of the manufacturing process of the semiconductor device shown in FIG. 1 to FIG. 3 and is a sectional view corresponding to the section plane of FIG. 3.

FIG. 5B is a sectional view of a step subsequent to that of FIG. 5A.

FIG. 5C is a sectional view of a step subsequent to that of FIG. 5B.

FIG. 5D is a sectional view of a step subsequent to that of FIG. 5C.

FIG. 5E is a sectional view of a step subsequent to that of FIG. 5D.

FIG. 5F is a sectional view of a step subsequent to that of FIG. 5E.

FIG. 5G is a sectional view of a step subsequent to that of FIG. 5F.

FIG. 6A is an illustrative partially enlarged sectional view showing an A portion of FIG. 3 in enlarged manner.

FIG. 6B is an illustrative partially enlarged sectional view of a comparative example.

FIG. 7 is a graph of measurement results of leak current.

### DESCRIPTION OF EMBODIMENTS

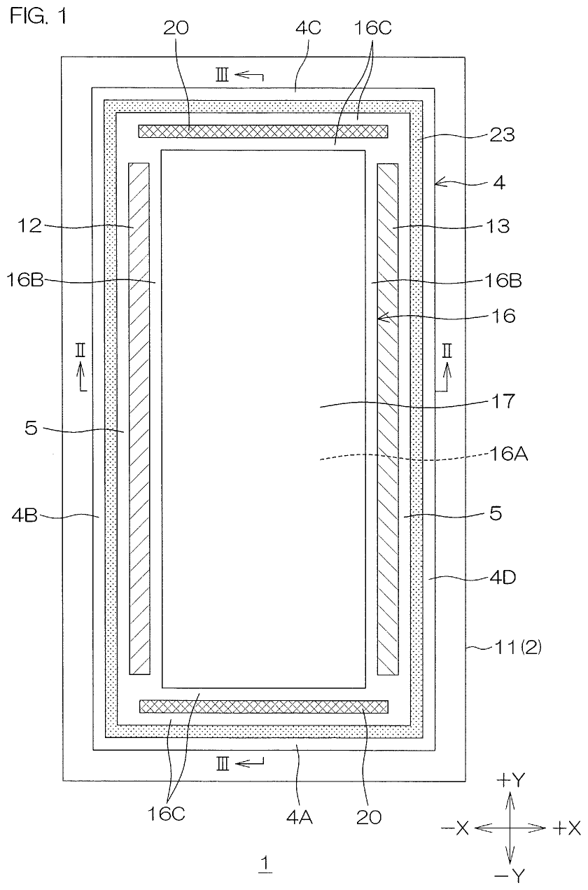

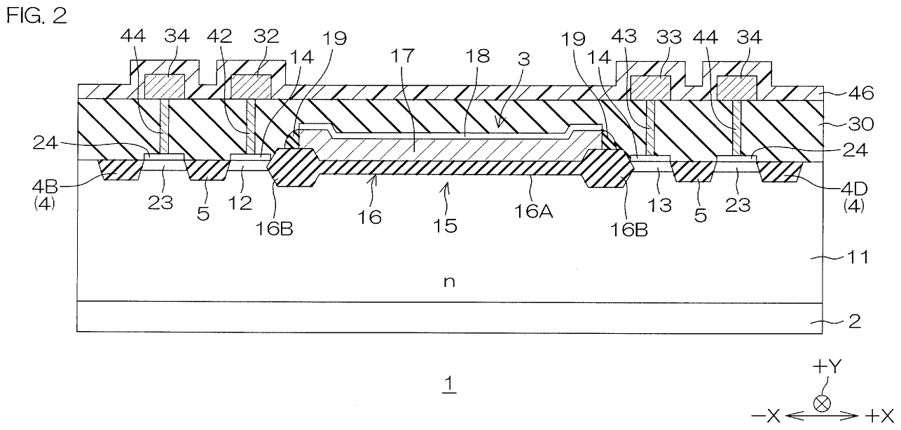

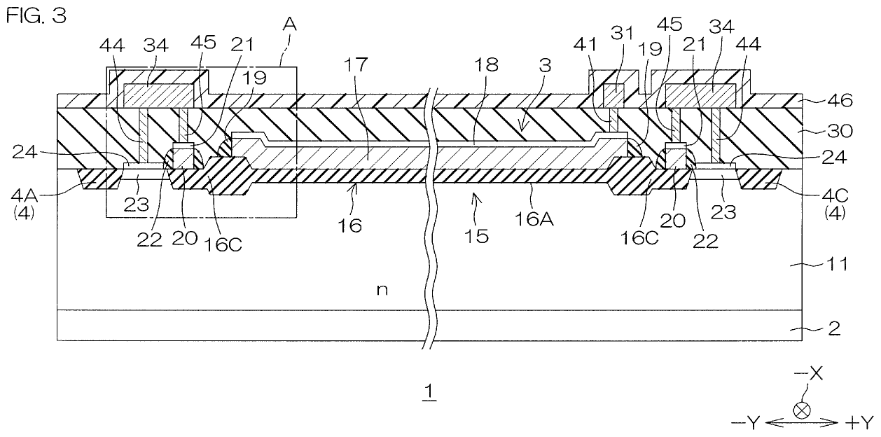

FIG. 1 is an illustrative plan view for describing the arrangement of a semiconductor device according to a preferred embodiment of the present invention. FIG. 2 is an illustrative sectional view taken along line II-II of FIG. 1. FIG. 3 is an illustrative sectional view taken along line III-III of FIG. 1.

For convenience of description, a +X direction, a −X direction, a +Y direction, and a −Y direction shown in FIG. 1, FIG. 2, and FIG. 3 are used at times in the following description. The +X direction is a predetermined direction along a front surface of the semiconductor device 1 in plan view and the +Y direction is a direction along the front surface of the semiconductor device 1 and is a direction that is orthogonal to the +X direction. The −X direction is a direction opposite to the +X direction and the −Y direction is a direction opposite to the +Y direction. The +X direction and the −X direction shall be referred to simply as the “X direction” when referred to collectively, and the +Y direction and the −Y direction shall be referred to simply as the “Y direction” when referred to collectively.

The semiconductor device 1 has a p type semiconductor substrate 2 that is constituted, for example, of silicon and a p type MOSFET 3 on the semiconductor substrate 2.

An element isolation portion 4 is formed in the semiconductor substrate 2 such as to surround a region in which the p type MOSFET 3 is formed. In the present preferred embodiment, the element isolation portion 4 is constituted of an STI (shallow trench isolation) structure with which an insulating film is embedded in a trench formed in the semiconductor substrate 2. The element isolation portion 4 is formed to a rectangular annular shape in plan view and is constituted of a pair of rectilinear portions 4A and 4C extending in the X direction at an interval in the Y direction and a pair of rectilinear portions 4B and 4D extending in the Y direction at an interval in the X direction.

The p type MOSFET 3 includes an n type well 11 formed in the semiconductor substrate 2 and a p type source region 12 and a p type drain region 13 that are formed at an interval in the X direction in a surface layer region of the n type well 11. The n type well 11 is an example of a “semiconductor layer” of the present invention. Silicide films 14 constituted of cobalt silicide (CoSi₂) are formed on front surfaces of the p type source region 12 and the p type drain region 13.

A region between the p type source region 12 and the p type drain region 13 is a channel region 15. A gate electrode 17 is formed across a gate insulating film 16 such as to oppose the channel region 15.

The gate electrode 17 is constituted, for example, of polysilicon. A silicide film 18 constituted, for example, of cobalt silicide is formed on a front surface of the gate electrode 17. Both side surfaces of the gate electrode 17 are covered by a side wall 19 that is constituted of an insulating material such as SiN, etc.

The gate insulating film 16 is constituted of an insulating film such as an SiO₂ film, etc. The gate insulating film 16 is constituted of a major portion 16A of rectangular shape in plan view on which the gate electrode 17 is disposed and an extension portion that is formed in a periphery of the major portion 16A. In plan view, the extension portion is constituted of first extension portions 16B each extending outward from each of both sides of the major portion 16A in the X direction (see FIG. 1 and FIG. 2) and second extension portions 16C each extending outward from each of both sides of the major portion 16A in the Y direction (see FIG. 1 and FIG. 3). The second extension portions 16C are an example of an “extension portion” of the present invention.

Leak current suppressing electrodes 20 are each formed on each of the second extension portions 16C at both sides. The leak current suppressing electrodes 20 are of rectangular shapes that are long in the X direction in plan view. In this preferred embodiment, as viewed from the Y direction, a −X direction end of each leak current suppressing electrode 20 is positioned between a −X direction end of the gate electrode 17 and a −X direction end of the p type source region 12 and a +X direction end of each leak current suppressing electrode 20 is positioned between a +X direction end of the gate electrode 17 and a +X direction end of the p type drain region 13.

The leak current suppressing electrodes 20 are constituted of the same material as the gate electrode 17. Silicide films 21 constituted, for example, of cobalt silicide are formed on front surfaces of the leak current suppressing electrodes 20. Both side surfaces of each leak current suppressing electrode 20 are covered by side walls 22 constituted of an insulating material such as SiN, etc.

As shown in FIG. 2, in the semiconductor substrate 2, region isolation portions 5 are formed in intermediate regions between both sides of the gate insulating film 16 in the X direction and the corresponding rectilinear portions 4B and 4D of the element isolation portion 4. In this preferred embodiment, the region isolation portions 5 are each constituted of an STI structure with which an insulating film is embedded in a trench formed in the semiconductor substrate 2. The above-described p type source region 12 is formed between a −X direction edge of the gate insulating film 16 and the above-described region isolation portion 5 at the −X direction side and the p type drain region 13 is formed between a +X direction edge of the gate insulating film 16 and the region isolation portion 5 at the +X direction side.

As shown in FIG. 2, in a surface layer region of the n type well 11, n⁺ type back gate regions 23 are respectively formed in a region between the region isolation portion 5 at the −X direction side and the rectilinear portion 4B at the −X direction side of the element isolation portion 4 and a region between the region isolation portion 5 at the +X direction side and the rectilinear portion 4D at the +X direction side of the element isolation portion 4.

Also, as shown in FIG. 3, in a surface layer region of the n type well 11, n⁺ type back gate regions 23 are respectively formed in a region between a −Y direction side edge of the gate insulating film 16 and the rectilinear portion 4A at the −Y direction side of the element isolation portion 4 and a region between a +Y direction side edge of the gate insulating film 16 and the rectilinear portion 4C at the +Y direction side of the element isolation portion 4.

As shown in FIG. 1, the n⁺ type back gate regions 23 shown in FIG. 2 and the n⁺ type back gate regions 23 shown in FIG. 3 are connected and a shape in plan view of an entirety of the n⁺ type back gate regions 23 is a rectangular annular shape. As shown in FIG. 2 and FIG. 3, silicide films 24 constituted, for example, of cobalt silicide are formed on front surfaces of the n⁺ type back gate regions 23.

An interlayer insulating film 30 that covers an entire area of a front surface of the semiconductor substrate 2 is formed on the front surface of the semiconductor substrate 2. The interlayer insulating film 30 contains SiO₂ or SiN. The interlayer insulating film 30 may be formed of a single insulating film or of a laminated film of a plurality of insulating films.

A plurality of wirings 31 to 34 are formed on the interlayer insulating film 30. Each of the wirings 31 to 34 contains a conductive material, for example, aluminum, etc. The plurality of wirings 31 to 34 include a gate wiring 31 (see FIG. 3), a source wiring 32 (see FIG. 2), a drain wiring 33 (see FIG. 2), and a back gate wiring 34 (see FIG. 2 and FIG. 3).

The gate wiring 31 is electrically connected to the gate electrode 17 via a contact plug 41 that is formed penetratingly through the interlayer insulating film 30. The source wiring 32 is electrically connected to the p type source region 12 via a contact plug 42 that is formed penetratingly through the interlayer insulating film 30.

The drain wiring 33 is electrically connected to the p type drain region 13 via a contact plug 43 that is formed penetratingly through the interlayer insulating film 30. The back gate wiring 34 is electrically connected to the n⁺ type back gate regions 23 via a contact plug 44 that is formed penetratingly through the interlayer insulating film 30. The back gate wiring 34 is further electrically connected to the leak current suppressing electrodes 20 (see FIG. 3) via contact plugs 45 that are formed penetratingly through the interlayer insulating film 30.

In use, a predetermined voltage (for example, of 40 V to 60 V) by which the source wiring 32 side becomes positive is applied between the source wiring 32 and the drain wiring 33. Also, the same voltage as a voltage applied to the source wiring 32 (hereinafter referred to as the “source voltage”) is applied to the back gate wiring 34. In this state, with the drain wiring 33 being at a reference potential (0 V), an off voltage (0 V) or an on voltage (−40 V to −60 V) is applied to the gate electrode 17.

When the off voltage is applied to the gate electrode 17, a current does not flow between the p type source region 12 and the p type drain region 13. When the on voltage is applied to the gate electrode 17, holes gather at a surface layer portion of the channel region 15 and an inversion layer is formed. A current thereby flows between the p type source region 12 and the p type drain region 13.

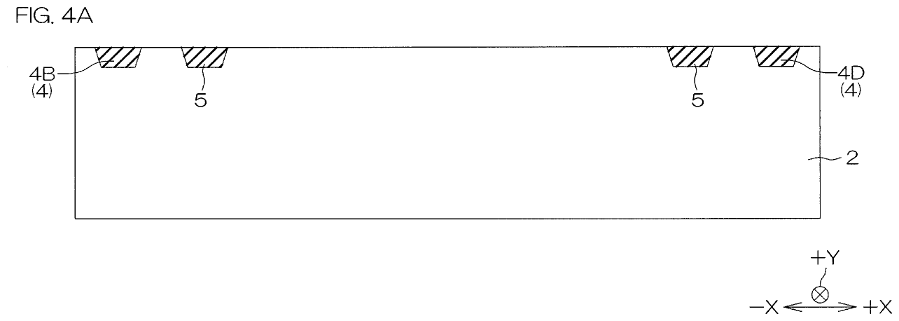

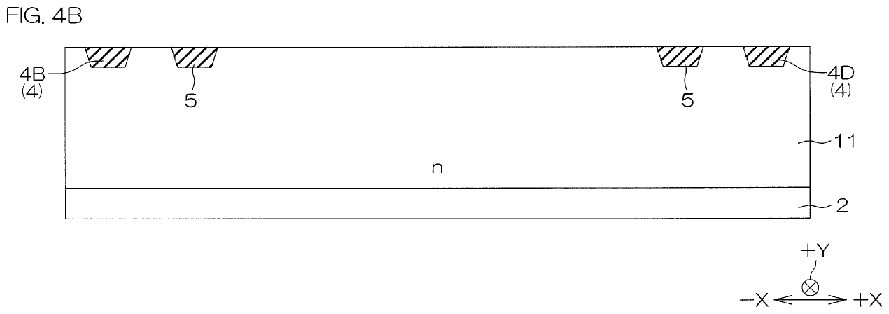

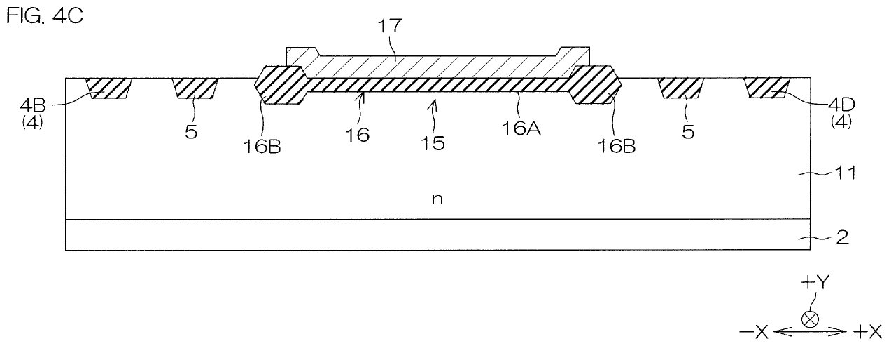

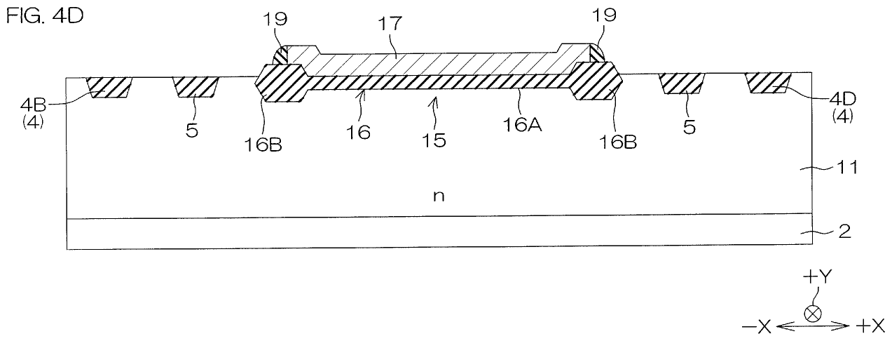

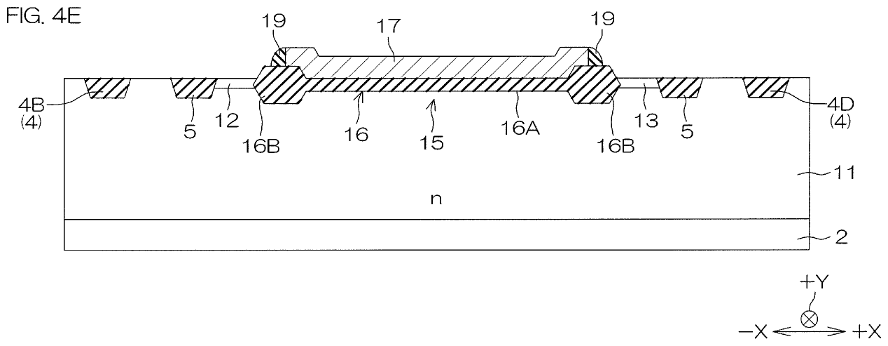

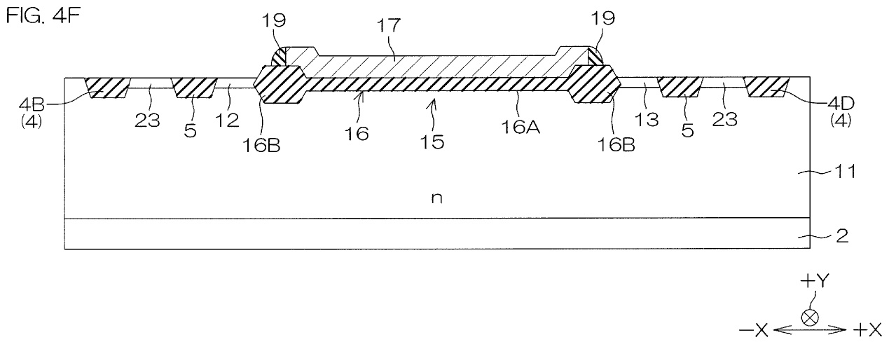

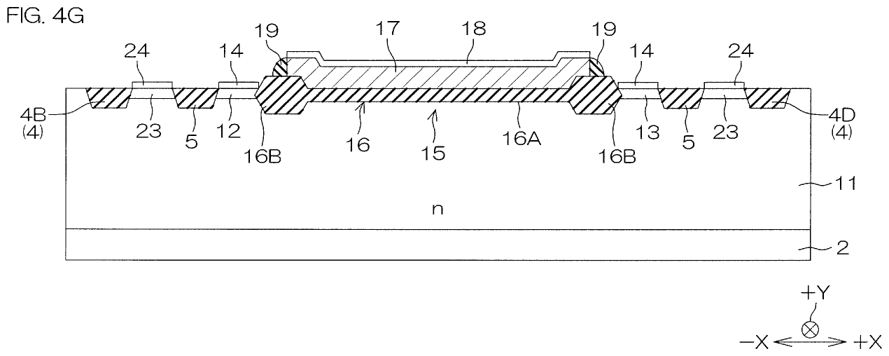

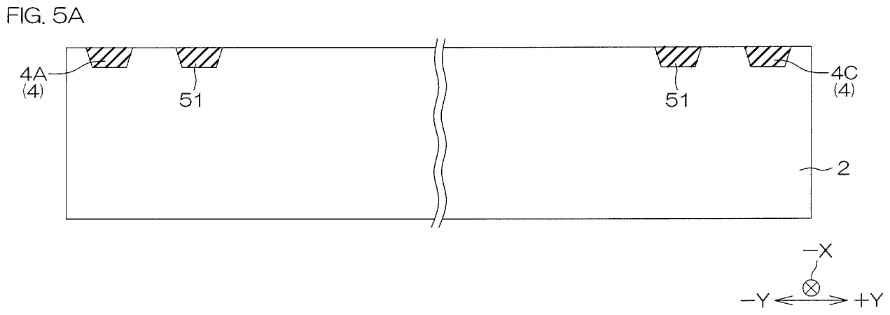

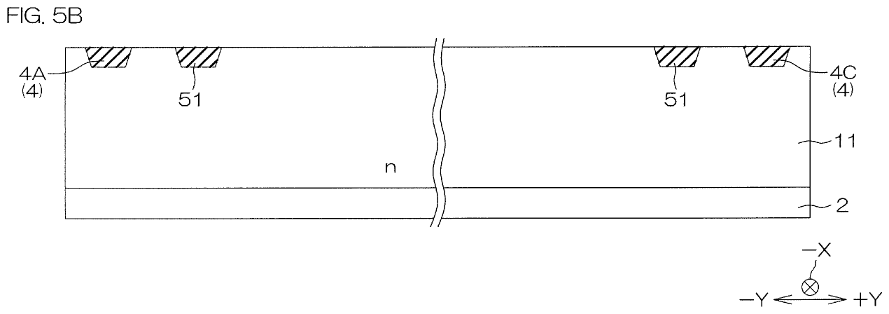

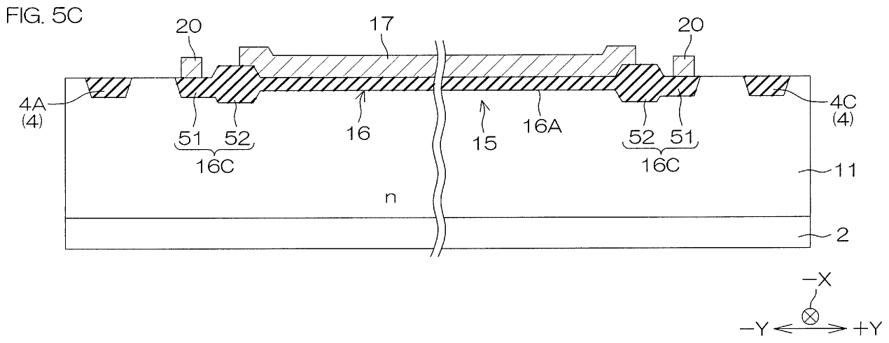

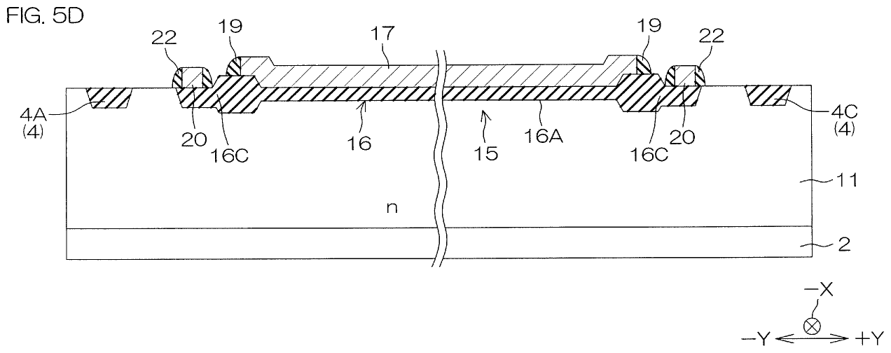

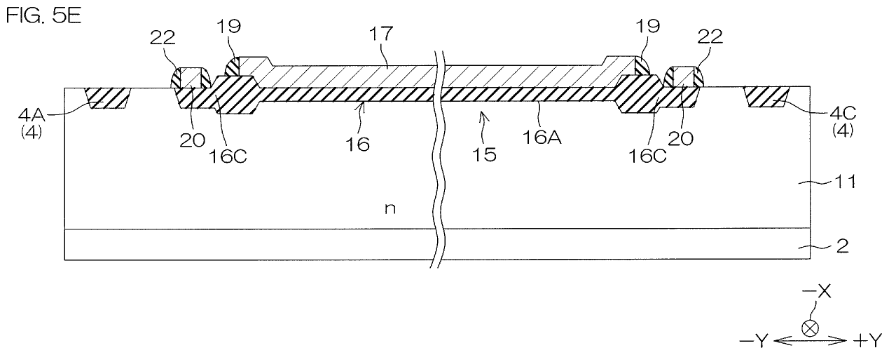

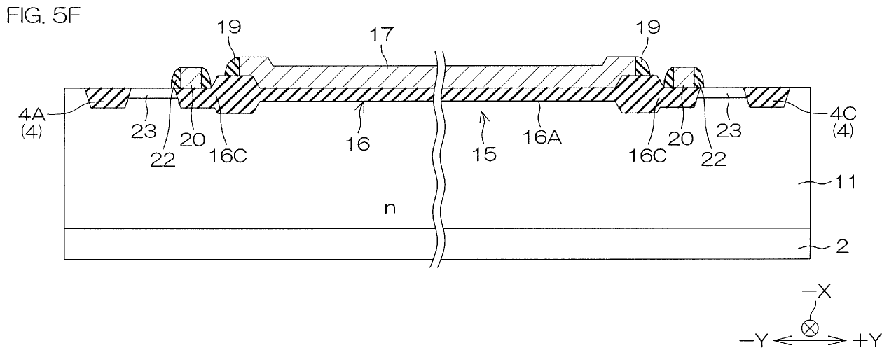

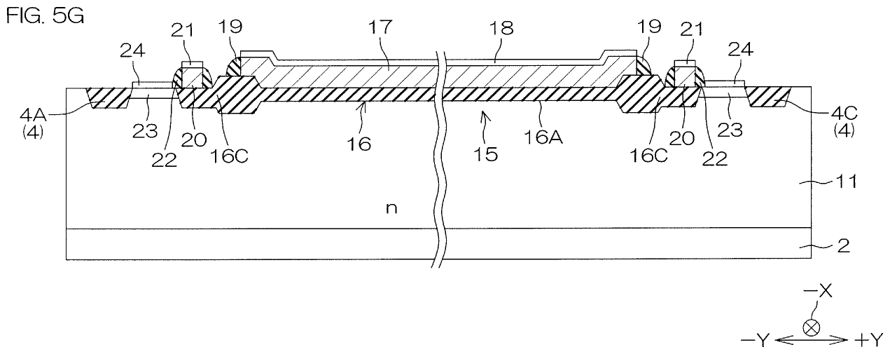

FIG. 4A to FIG. 4G are sectional views of an example of a manufacturing process of the semiconductor device 1 shown in FIG. 1 to FIG. 3 and are sectional views corresponding to the section plane of FIG. 2. FIG. 5A to FIG. 5G are sectional views of the example of the manufacturing process of the semiconductor device 1 shown in FIG. 1 to FIG. 3 and are sectional views corresponding to the section plane of FIG. 3.

Referring to FIG. 4A and FIG. 5A, the element isolation portion 4, the region isolation portions 5, and first insulating layers 51 that become portions of the second extension portions 16C of the gate insulating film 16 are formed at the same time in a surface layer portion of the semiconductor substrate 2. Specifically, first trench of a rectangular annular shape in plan view is formed such as to surround the region in which the p type MOSFET 3 will be formed and at the same time, second trench of a rectangular annular shape in plan view is formed at intervals from the first trench at inner sides of the first trench. An insulating film constituted of silicon oxide is then embedded in the first trench and the second trench.

The element isolation portion 4 is formed by the insulating films embedded in the first trench. The region isolation portions 5 are formed by the insulating films embedded respectively in two portions of the second trench, extending in parallel to the Y direction. The first insulating layers 51 that become portions of the second extension portions 16C are formed by the insulating films embedded respectively in two portions of the second trench, extending in parallel to the X direction.

Next, as shown in FIG. 4B and FIG. 5B, the n type well 11 is formed inside the semiconductor substrate 2. To form the n type well 11, for example, an ion implantation mask (not shown), having an opening in a region in which the n type well 11 is to be formed, is formed. An n type impurity is then doped into the semiconductor substrate 2 via the ion implantation mask to form the n type well 11. The ion implantation mask is removed after the n type well 11 is formed.

Next, as shown in FIG. 4C and FIG. 5C, by thermally oxidizing the semiconductor substrate 2 (n type well 11) selectively, the major portion 16A, the first extension portions 16B, and second insulating layers 52 that become portions of the second extension portions 16C of the gate insulating film 16 constituted of thermal oxide films are formed in a surface layer portion of the semiconductor substrate 2. In this process, at least portions of the first insulating layers 51 are made integral to the second insulating layers 52. The second extension portions 16C are formed by the first insulating layers 51 and the second insulating layers 52. The gate insulating film 16 is thereby formed.

Also, the gate electrode 17 constituted of polysilicon is formed on the major portion 16A of the gate insulating film 16 and, at the same time, the leak current suppressing electrodes 20 constituted of polysilicon are formed on the second extension portions 16C. To form the gate electrode 17 and the leak current suppressing electrodes 20, first, a polysilicon film is formed on the front surface of the semiconductor substrate 2 such as to cover the gate insulating film 16. Thereafter, unnecessary portions of the polysilicon film are removed by photolithography and etching. The gate electrode 17 and the leak current suppressing electrodes 20 are thereby formed.

Next, as shown in FIG. 4D and FIG. 5D, by photolithography and etching, the side wall 19 is formed at both sides of the gate electrode 17 and, at the same time, side walls 22 are formed at both sides of each leak current suppressing electrode 20. The side walls 19 and 20 are constituted, for example, of SiN.

Next, as shown in FIG. 4E and FIG. 5E, the p type source region 12 and the p type drain region 13 are formed. To form the p type source region 12 and the p type drain region 13, for example, an ion implantation mask (not shown), having openings in regions in which the p type source region 12 and the p type drain region 13 are to be formed, is formed. A p type impurity is then doped into the semiconductor substrate 2 (n type well 11) via the ion implantation mask to form the p type source region 12 and the p type drain region 13. After the p type source region 12 and the p type drain region 13 are formed, the ion implantation mask is removed.

Next, as shown in FIG. 4F and FIG. 5F, the n⁺ type back gate regions 23 are formed. To form the n⁺ type back gate regions 23, for example, an ion implantation mask (not shown), having an opening in a region in which the n⁺ type back gate regions 23 are to be formed, is formed. An n type impurity is then doped into the semiconductor substrate 2 (n type well 11) via the ion implantation mask to form the n⁺ type back gate regions 23. After the n⁺ type back gate regions 23 are formed, the ion implantation mask is removed.

Next, as shown in FIG. 4G and FIG. 5G, the silicide films 14, 18, 21, and 24 are formed respectively on the front surfaces of the p type source region 12 and the p type drain region 13, the front surface of the gate electrode 17, the front surfaces of the leak current suppressing electrodes 20, and the front surfaces of the n+ type back gate regions 23. To form the silicide films 14, 18, 21, and 24, cobalt films (not shown) are formed on the front surfaces of the p type source region 12 and the p type drain region 13, the front surface of the gate electrode 17, the front surfaces of the leak current suppressing electrodes 20, and the front surfaces of the n+ type back gate regions 23. By then performing a heat treatment on the cobalt film, the silicide films 14, 18, 21, and 24 are formed. Thereafter, the cobalt films are removed.

Next, the interlayer insulating film 30, the contact plugs 41 to 45, the wirings 31 to 34, and a front surface protective film 46 are formed successively on the semiconductor substrate 2 to manufacture the semiconductor device 1 such as shown in FIG. 1 to FIG. 3.

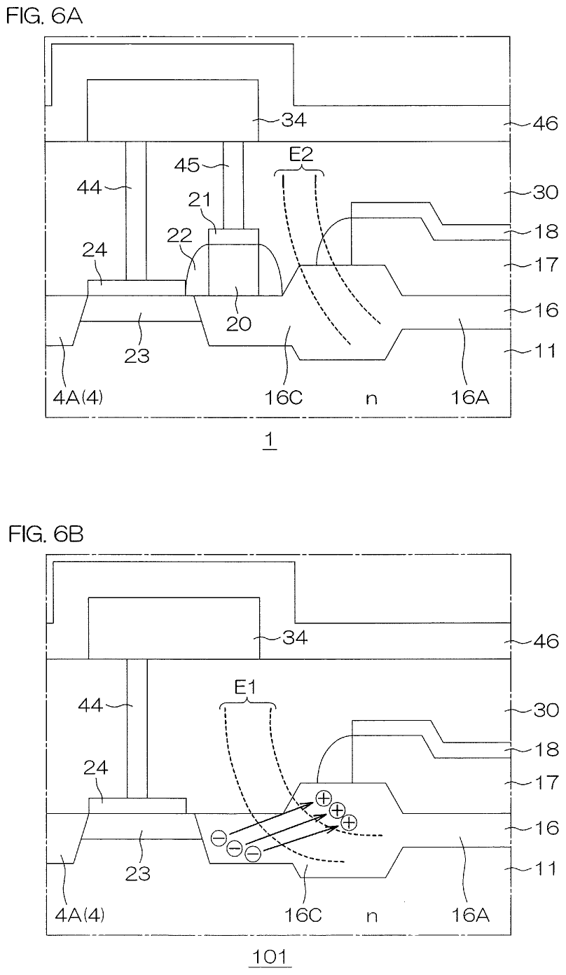

In the preferred embodiment, the leak current suppressing electrodes 20 are formed on the second extension portions 16C of the gate insulating film 16. The leak current suppressing electrodes 20 are electrically connected to the back gate wiring 34. The voltage equal to the voltage applied to the source wiring 32 is thus applied to the leak current suppressing electrodes 20. Thereby, with the preferred embodiment, a leak current flowing from the p type source region 12 to the p type drain region 13 via a peripheral region of the gate electrode 17 when the off voltage is applied to the gate electrode 17 can be reduced. Degradation with time of the p type MOSFET 3 can thereby be suppressed. The reason for this shall now be described with reference to FIG. 6A and FIG. 6B.

FIG. 6A is an illustrative partially enlarged sectional view showing an A portion of FIG. 3 in enlarged manner. However, the hatching is omitted in FIG. 6A. FIG. 6B is an enlarged sectional view that is an illustrative partially enlarged sectional view corresponding to the sectional view of FIG. 6A of a semiconductor device 101 (hereinafter referred to as the “comparative example”) that, with respect to the semiconductor device 1 of the preferred embodiment, is not provided with the leak current suppressing electrodes 20.

It shall be deemed that in the preferred embodiment and the comparative example, a voltage (for example, of 40 V) that is equal to the source voltage is applied to the semiconductor substrate 2. It shall be deemed that 0 V is applied as a drain voltage to the drain wiring 33.

Referring to FIG. 6B, in the comparative example, when the on voltage (for example, of −40 V) is applied to the gate electrode 17, an electric field is generated as indicated by broken lines E1 in the peripheral region of the gate electrode 17.

By this electric field E1, positive charges inside each second extension portion 16C of the gate insulating film 16 are drawn toward the gate electrode 17 side. Negative charges thus accumulate in a bottom portion of the second extension portion 16C and thus an inversion layer is formed in a region of the n type well 11 directly below the second extension portion 16C as well.

When, in this state, the off voltage (for example, of 0 V) is applied to the gate electrode 17, the negative charges remain in the bottom portion of the second extension portion 16C because the bottom portion of the second extension portion 16C is separated further from the gate electrode 17 than a portion of the gate insulating film 16 directly below the gate electrode 17. Thus, when the p type MOSFET 3 is off, a leak current flows from the p type source region 12 to the p type drain region through the region of the n type well 11 directly below the second extension portion 16C.

Referring to FIG. 6A, in the preferred embodiment, when the on voltage is applied to the gate electrode 17, an electric field is generated as indicated by broken lines E2 in the peripheral region of the gate electrode 17. However, with the preferred embodiment, the leak current suppressing electrodes 20 are provided on the second extension portions 16C of the gate insulating film 16. Also, the voltage applied to the n⁺ type back gate regions 23 (the voltage applied to the semiconductor substrate 2) is applied to the leak current suppressing electrodes 20.

Equal voltages are thus applied to an upper surface and a lower surface of each second extension portion 16C. Thereby, in the preferred embodiment, the electric field from the gate electrode 17 into the second extension portion 16C is relaxed in comparison to the comparative example. Thereby, when the p type MOSFET 3 is on, the amount of negative charges accumulated in the bottom portion of the second extension portion 16C is reduced significantly in comparison to the comparative example. Consequently, the leak current that flows from the p type source region 12 to the p type drain region through the region of the n type well 11 directly below the second extension portion 16C when the p type MOSFET 3 is off is reduced.

An experiment for measuring the leak current was performed on the preferred embodiment and a plurality of conventional p type MOSFETs not provided with the leak current suppressing electrodes 20 (conventional examples). Specifically, with the preferred embodiment and the conventional examples, after turning on the p type MOSFET for a predetermined time, the p type MOSFET was turned off and the leak current (source-drain current) was measured. Such an experiment was performed with the on duration of the p type MOSFET being varied.

When the p type MOSFET was on, a gate voltage Vg was set to −120 V and the temperature was set to 125° C. On the other hand, when the p type MOSFET was off, a gate voltage Vg was set to 0 V, the drain-source voltage was set to −0.1 V. and the temperature was set to 125° C.

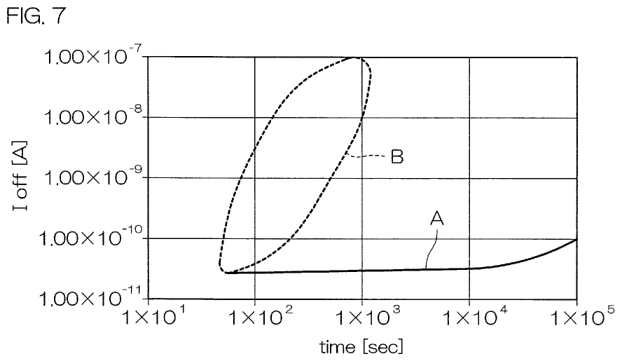

FIG. 7 is a graph of measurement results of the leak current. The abscissa of FIG. 7 represents the on duration (time [sec]) of the p type MOSFET and the ordinate represents the leak current (Ioff [A]). Also, a curve A indicates the measurement results for the preferred embodiment. A broken line B represents a range of the measurement results for the plurality of conventional examples.

From FIG. 7, it can be understood that with the preferred embodiment, the leak current is reduced in comparison to the conventional examples.

Although the preferred embodiment of the present invention has been described above, this invention can be implemented in yet other preferred embodiments. For example, with the preferred embodiment described above, portions of the second extension portions 16C are formed when the element isolation portion 4 is formed. However, entireties of the second extension portions 16C may instead be formed when the major portion 16A of the gate insulating film 16 is formed. In this case, there is no need to form portions of the second extension portions 16C when the element isolation portion 4 is formed.

Also, the present invention can also be applied to a semiconductor device having an n type MOSFET. With the n type MOSFET, the n type well 11 of the preferred embodiment is replaced by a p type well. Also, the p type source region 12 and the p type drain region 13 of the preferred embodiment are respectively replaced by an n type source region and an n type drain region. Also, the n⁺ type back gate regions 23 are replaced by p⁺ type back gate regions.

In use, a predetermined voltage (for example, of 40 V to 60 V) by which the drain wiring 33 becomes positive is applied between the source wiring 32 and the drain wiring 33. Also, the same voltage as the source voltage is applied to the back gate wiring 34 (semiconductor substrate 2). In this state, with the source wiring 32 being at a reference potential (0 V), an off voltage (0 V) or an on voltage (40 V to 60 V) is applied to the gate electrode 17.

When the off voltage is applied to the gate electrode 17, a current does not flow between the n type source region and the n type drain region. When the on voltage is applied to the gate electrode 17, electrons gather at a surface layer portion of the channel region 15 and an inversion layer is formed. A current thereby flows between the n type source region and the n type drain region.

While preferred embodiments of the present invention have been described in detail, these are merely specific examples used to clarify the technical contents of the present invention and the present invention should not be interpreted as being limited to these specific examples and the scope of the present invention is to be limited only by the appended claims.

The present application corresponds to Japanese Patent Application No. 2019-221394 filed in the Japan Patent Office on Dec. 6, 2019 and the entire disclosure of this application is incorporated herein by reference.

### REFERENCE SIGNS LIST

1 semiconductor device
2 semiconductor substrate
3 p type MOSFET
4 element isolation portion
4A to 4D rectilinear portion
5 region isolation portion
11 n type well
12 p type source region
13 p type drain region
14 silicide film
15 channel region
16 gate insulating film
16A major portion
16B first extension portion
16C second extension portion
17 gate electrode
18 silicide film
19 side wall
20 leak current suppressing electrode
21 silicide film
22 side wall
23 n⁺ type back gate region
24 silicide film
30 interlayer insulating film
31 gate wiring
32 source wiring
33 drain wiring
34 back gate wiring
41 to 45 contact plug
46 front surface protective film
51 first insulating layer
52 second insulating layer

1. A semiconductor device comprising:
a semiconductor layer;
a source region and a drain region that are formed in the semiconductor layer and at an interval in a first direction;
a gate insulating film that is formed such as to cover a channel region between the source region and the drain region; and
a gate electrode that is formed on the gate insulating film and opposes the channel region across the gate insulating film: and
wherein the gate insulating film has a major portion on which the gate electrode is formed and an extension portion projecting outward from each of both sides of the major portion in a second direction orthogonal to the first direction and a leak current suppressing electrode is formed on the extension portion.

2. The semiconductor device according to claim 1, wherein a voltage equal to a voltage applied to the semiconductor layer is applied to the leak current suppressing electrode.

3. The semiconductor device according to claim 1, wherein a voltage equal to a voltage applied to the source region is applied to the leak current suppressing electrode and the semiconductor layer.

4. The semiconductor device according to claim 1, wherein a back gate region is formed in the semiconductor layer such as to surround the gate insulating film.

5. The semiconductor device according to claim 4, wherein an element isolation portion is formed in the semiconductor layer such as to surround the back gate region.

6. The semiconductor device according to claim 5, wherein the element isolation portion is an ST structure.

7. The semiconductor device according to claim 5, wherein at least a portion of the extension portion is formed in the same step as a step of forming the element isolation portion.

8. The semiconductor device according to claim 4, wherein the leak current suppressing electrode is electrically connected to the back gate region.

9. The semiconductor device according to claim 1, wherein the leak current suppressing electrode is formed in the same step as a step of forming the gate electrode.

10. A method for manufacturing semiconductor device that is a method for manufacturing a semiconductor device having a source region and a drain region that are formed at an interval in a first direction, a gate insulating film that is formed such as to cover an interval between the regions, and a gate electrode that is formed on the gate insulating film, the gate insulating film having a major portion on which the gate electrode is formed and an extension portion projecting outward from each of both sides of the major portion in a second direction orthogonal to the first direction, and
the method comprising: a step of forming a first insulating layer that becomes a portion of the extension portion in a surface layer portion of a semiconductor substrate;
a step of forming a first conductivity type well by selectively doping the semiconductor substrate with a first impurity of a first conductivity type:
a step of selectively thermally oxidizing the semiconductor substrate to form the major portion and at the same time form a second insulating layer that becomes a portion of the extension portion to form the gate insulating film having the extension portion that is constituted of the first insulating layer and the second insulating layer and the major portion;
a step of forming the gate electrode on the major portion and at the same time forming a leak current suppressing electrode on the extension portion; and
a step of forming the source region and the drain region by selectively doping the first conductivity type well with an impurity of a second conductivity type.

11. A method for manufacturing semiconductor device that is a method for manufacturing a semiconductor device having a source region and a drain region that are formed at an interval in a first direction, a gate insulating film that is formed such as to cover an interval between the regions, and a gate electrode that is formed on the gate insulating film, the gate insulating film having a major portion on which the gate electrode is formed and an extension portion projecting outward from each of both sides of the major portion in a second direction orthogonal to the first direction, and
the method comprising: a step of forming a first conductivity type well by selectively doping the semiconductor substrate with a first impurity of a first conductivity type;
a step of selectively thermally oxidizing the semiconductor substrate to form the gate insulating film;
a step of forming the gate electrode on the major portion and at the same time forming a leak current suppressing electrode on the extension portion; and
a step of forming the source region and the drain region by selectively doping the first conductivity type well with an impurity of a second conductivity type.

12. The method for manufacturing semiconductor device according to claim 10, further comprising: a step of forming a first conductivity type back gate region by selectively doping the first conductivity type well with a second impurity of the first conductivity type.

13. The method for manufacturing semiconductor device according to claim 10, further comprising: a step of electrically connecting the leak current suppressing electrode with the back gate region.
